(19) United States
(12) Patent Application Publication
(10) Pub. No.: US 2025/0104974 A1
(43) Pub. Date: Mar. 27, 2025

(54) Plasma Processing Device

(71) Applicant: Tokyo Electron Limited, Tokyo (JP)

(72) Inventors: Taro IKEDA, Yamanashi (JP); Toshifumi KITAHARA, Tokyo (JP)

(21) Appl. No.: 18/974,589

(22) Filed: Dec. 9, 2024

Related U.S. Application Data
(63) Continuation of application No. PCT/JP2023/020960, filed on Jun. 6, 2023.

(30) Foreign Application Priority Data
Jun. 20, 2022 (JP) 2022-098827

(51) Int. Cl. H01J 37/32; C23C 16/455

(52) U.S. Cl. CPC H01J 37/32229; C23C 16/45536; H01J 37/32238; H01J 2237/3321

(57) ABSTRACT

A plasma processing apparatus comprises a processing chamber, a waveguide, an electrode, an electromagnetic wave emission part and a multipactor discharge part. A plasma generation space is formed in the processing chamber. Electromagnetic waves for generating plasma are applied to the electrode. The waveguide is disposed along an outer circumference of the electrode. The electromagnetic wave emission part is made of a dielectric material and configured to emit the electromagnetic waves into the plasma generation space. The multipactor discharge part is a gap formed between the electrode and the electromagnetic wave emission part and faces the plasma generation space.

### CROSS-REFERENCE TO RELATED APPLICATIONS

This application is a bypass continuation application of International Application No. PCT/JP2023/020960 having an international filing date of Jun. 6, 2023 and designating the United States, the International Application being based upon and claiming the benefit of priority from the Japanese Patent Application No. 2022-098827 filed on Jun. 20, 2022, the entire contents of which are incorporated herein by reference.

### TECHNICAL FIELD

This disclosure relates to a plasma processing apparatus.

### BACKGROUND

For example, Japanese Laid-open Patent Publication No. 2021-96934 discloses a plasma processing apparatus including an upper electrode, a lower electrode, and an electromagnetic wave emission part. The electromagnetic wave emission part is disposed at a height between the height of the upper electrode and the height of the lower electrode, and is opened toward the center of a processing chamber.

### SUMMARY

The present disclosure provides a plasma processing apparatus capable of stably igniting plasma.

According to one aspect of the present disclosure, a plasma processing apparatus is provided. The plasma processing apparatus comprises a processing chamber where a plasma generation space is formed, an electrode to which electromagnetic waves for generating plasma are applied, a waveguide disposed along an outer circumference of the electrode, an electromagnetic wave emission part made of a dielectric material and configured to emit the electromagnetic waves into the plasma generation space, and a multipactor discharge part that is a gap formed between the electrode and the electromagnetic wave emission part and faces the plasma generation space.

### BRIEF DESCRIPTION OF THE DRAWINGS

FIG. 1 is a schematic cross-sectional view showing an example of a plasma processing apparatus according to one embodiment.

FIG. 2 is a schematic cross-sectional view showing another example of a plasma processing apparatus according to one embodiment.

FIGS. 3A to 3D are enlarged views of a multipactor discharge part according to one embodiment.

FIGS. 4A to 4F are diagrams for explaining multipactor discharge.

FIGS. 5A and 5B are diagrams for explaining an aspect ratio of a gap of a multipactor discharge part according to one embodiment.

FIG. 6 shows an example of the relationship between a distance of a gap of a multipactor discharge part and a frequency of high-frequency waves according to one embodiment.

FIG. 7 shows an example of the relationship between a distance of a gap of a multipactor discharge part and a frequency of high-frequency waves according to one embodiment.

### DETAILED DESCRIPTION

Hereinafter, embodiments of the present disclosure will be described with reference to the accompanying drawings. Like reference numerals will be used for like parts throughout the drawings, and redundant description thereof may be omitted.

In this specification, directions such as parallel, right-angled, orthogonal, horizontal, vertical, up and down, and left and right are allowed to deviate without spoiling the effect of the embodiment. The shape of a corner is not limited to a right angle and may be rounded in an arch shape. The terms parallel, right-angled, orthogonal, horizontal, vertical, circular, and equal may include substantially parallel, substantially right-angled, substantially orthogonal, substantially horizontal, substantially vertical, substantially circular, and substantially equal, respectively.

### Plasma Processing Apparatus

In film formation performed by an atomic layer deposition (ALD) apparatus, ON and OFF of plasma is repeatedly controlled in a short period of time. Therefore, it is important to perform impedance matching at a high speed and ignite plasma at a high speed. On the other hand, in a process that requires the supply of a high frequency of a relatively low power and the use of a negative gas in an ALD apparatus, plasma ignition may not be stable.

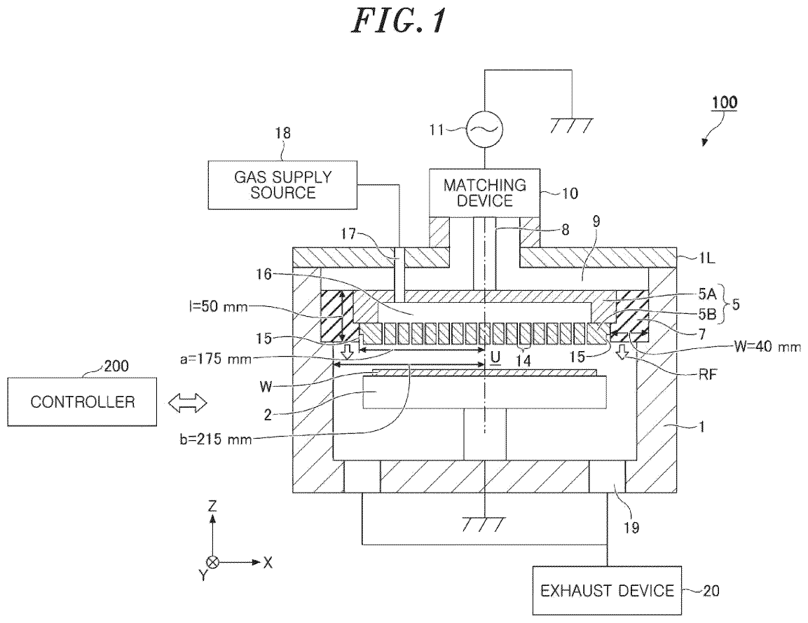

Accordingly, in a plasma processing apparatus according to one embodiment of the present disclosure, in order to realize stable plasma ignition in an ALD apparatus, plasma ignition using multipactor discharge is proposed. Hereinafter, a configuration of a plasma processing apparatus 100 according to one embodiment of the present disclosure will be described with reference to FIG. 1. FIG. 1 is a schematic cross-sectional view showing an example of the plasma processing apparatus 100 according to one embodiment.

The plasma processing apparatus 100 includes a processing chamber 1 having an upper opening, a lid 1L that seals the upper opening of the processing chamber 1, a placing table 2 (a lower electrode, a stage) disposed in the processing chamber 1, and a plasma generation source disposed above the placing table 2.

The plasma generation source has an upper electrode 5 disposed to face the placing table 2, and an electromagnetic wave emission part 7 having an electromagnetic wave emission port. A plasma generation space U is formed between the upper electrode 5 and the placing table 2 in the processing chamber 1. The electromagnetic wave emission part 7 is made of a dielectric material such as alumina (Al₂O₃). Electromagnetic waves RF are emitted from the lower part of the electromagnetic wave emission part 7. The electromagnetic wave emission part 7 is an electromagnetic wave introducing part, and a stepped portion having an annular upper surface is formed on the inner wall surface of the processing chamber 1. The electromagnetic wave emission part 7 is disposed on the upper surface while being engaged with the stepped portion, and is supported by the upper surface. The electromagnetic wave emission part 7 is fitted along the entire circumference of the processing chamber 1. In other words, the electromagnetic waves RF are emitted downward from the electromagnetic wave emission part 7 disposed in the circumferential direction of the processing chamber 1 around the entire circumference.

A substrate W is placed on the placing table 2. The substrate W is not particularly limited as long as it is subjected to plasma processing. The substrate W may be a semiconductor substrate, an insulating substrate such as glass or alumina, or a metal substrate.

A gas in the processing chamber 1 can be exhausted to the outside by an exhaust device 20 through a gas exhaust port 19. A processing gas is supplied into the processing chamber 1 from a gas supply source 18 through a supply line 17. Specifically, the upper electrode 5 has a shower structure having therein a gas diffusion space 16. The supply line 17 penetrates through the lid 1L, and is connected to the gas diffusion space 16 via the waveguide 9. The upper electrode 5 in this example has a metallic shower plate structure, and has the gas diffusion space 16 into which the processing gas is introduced, and a plurality of gas holes 14 that connect the gas diffusion space 16 to the space in the processing chamber 1. The upper electrode 5 includes an upper metal member 5A having a recess on the bottom surface thereof, and a lower metal member 5B having the plurality of gas holes 14. The gas diffusion space 16 is formed at the position of the recess between the metal members. The processing gas introduced into the gas diffusion space 16 is supplied into the processing chamber 1 through the plurality of gas holes 14 formed in the lower area of the upper electrode 5. The upper electrode 5 is an example of an electrode to which electromagnetic waves for plasma generation are applied.

The waveguide 9 is formed along the outer circumference of the upper electrode 5 between the upper electrode 5, the bottom surface of the lid 1L, and the inner surface of the processing chamber 1. The power of electromagnetic waves is supplied from a power supply 11 to a position above the upper electrode 5 through a first matching device 10 and a power transmission line 8. The supplied electromagnetic waves travel radially in the horizontal direction through the waveguide 9. When the electromagnetic waves are brought into contact with the inner surface of the processing chamber 1, they travel downward, pass through the electromagnetic wave emission part 7, and are emitted from the bottom surface and a multipactor discharge part 15 to be described later into the plasma generation space U. The electromagnetic waves may be electromagnetic waves in a VHF band or a microwave band.

When a processing gas is introduced into the processing chamber 1 and electromagnetic waves are introduced into the processing chamber 1 in a state where a pressure in the processing chamber 1 is reduced by the exhaust device 20 to a pressure at which plasma can be generated, plasma is generated in the plasma generation space U below the upper electrode 5. The plasma generation space U is located directly below the upper electrode 5. Further, one end of the power supply 11 is connected to the first matching device 10, and the other end thereof is connected to the ground. Further, the power transmission line 8 may be any one capable of transmitting electromagnetic waves in a VHF band or the like, and an electromagnetic wave transmission component may be a coaxial cable other than a waveguide. In this example, the placing table 2 is electrically connected to the ground, but it is also possible to apply high frequency waves or electromagnetic waves thereto.

The central axis extending vertically in the processing chamber 1 is set as the Z-axis. The axis perpendicular to the Z-axis is set as the X-axis, and the axis perpendicular to both the Z-axis and the X-axis is set as the Y-axis. In this case, the XY plane constitutes a horizontal plane. The central axis of the electromagnetic wave emission part 7 coincides with the central axis (Z-axis) of the processing chamber 1 in the vertical direction.

The upper electrode 5 has a circular planar shape when viewed from the top, and the position of the center thereof coincides with the position of the central axis (Z-axis) of the processing chamber 1 in the vertical direction. At the outer circumferential corner of the bottom surface of the upper electrode 5, a gap (space) formed as the notch of the upper electrode 5 exists between the upper electrode 5 and the electromagnetic wave emission part 7 around the entire circumference. The gap is an example of a multipactor discharge part 15 that is formed between the upper electrode 5 and the electromagnetic wave emission part 7 to face the plasma generation space U.

The electromagnetic wave emission part 7 is disposed at the end point of the waveguide 9. The lower part of the electromagnetic wave emission part 7 protrudes toward the inner circumference, and surrounds the notch of the upper electrode 5 disposed at the outer circumference of the upper electrode 5 from the outer circumference thereof. Accordingly, the multipactor discharge part 15 is disposed at a position in contact with the plasma generation space U, the upper electrode 5, and the electromagnetic wave emission part 7. The radial cross section of the gap of the multipactor discharge part 15 has a rectangular shape.

The multipactor discharge part 15 is formed in an annular shape to surround the central axis of the processing chamber 1, and the gap of the multipactor discharge part 15 has an annular planar shape when viewed from the bottom of the upper electrode 5.

The multipactor discharge part 15 is disposed above the outer region (diameter 300 mm of the substrate W) of the substrate placement region of the lower electrode. In other words, since the plasma intensity tends to be high directly below the multipactor discharge part 15, the uniformity of the plasma intensity on the substrate W can be improved by moving the position of the multipactor discharge part 15 to be distant from the position directly above the substrate W. In the present embodiment, the multipactor discharge part 15 is disposed above the outer region of the placing table 2.

The controller 200 processes computer-executable instructions that cause the plasma processing apparatus 100 to execute various processes such as film formation and the like using an ALD method. The controller 200 may be configured to control individual components of the plasma processing apparatus 100 to perform various processes. In one embodiment, the controller 200 may be partially or entirely included in the plasma processing apparatus 100. The controller 200 may include a processing part, a storage part, and a communication interface. The controller 200 is realized by, for example, a computer. The processing part may be configured to perform various control operations by reading a program from the storage part and executing the read program. The program may be stored in the storage part in advance, or may be acquired via a medium when necessary. The acquired program is stored in the storage part, and is read from the storage part and executed by the processing part. The medium may be various storage media that are readable by a computer, or may be a communication line connected to the communication interface. The processing part may be a central processing unit (CPU). The storage part may include a random access memory (RAM), a read only memory (ROM), a hard disk drive (HDD), a solid state drive (SSD), or combination thereof. The communication interface may communicate with the plasma processing apparatus 100 via a communication line such as a local area network (LAN).

As described above, the plasma processing apparatus 100 according to the embodiment includes the upper electrode 5, the lower electrode (the placing table 2), and the electromagnetic wave emission part 7. The upper electrode 5 has the plurality of gas holes 14, and is configured to discharge a processing gas into the processing chamber 1. The lower electrode (the placing table 2) is disposed to hold a substrate in the processing chamber 1. A notch (groove) is formed at the outer circumferential corner of the upper electrode 5, and constitutes a gap between the electromagnetic wave emission part 7 and the multipactor discharge part 15.

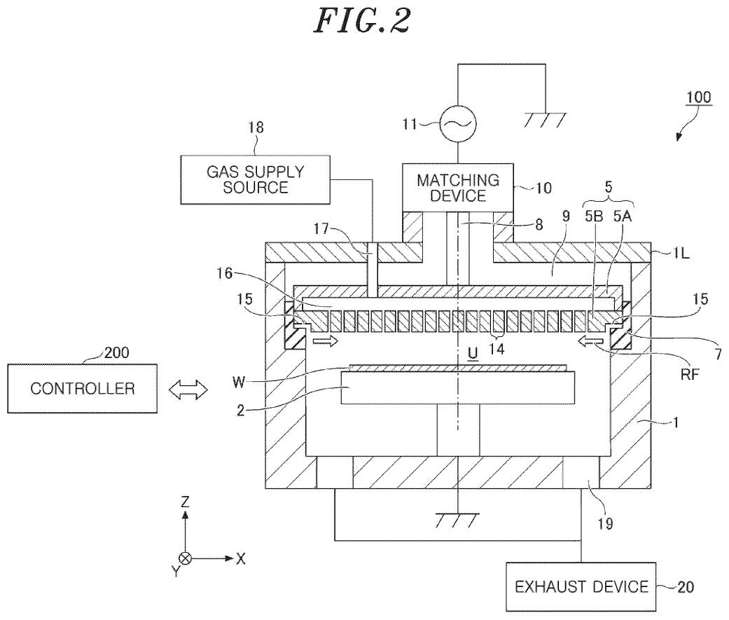

FIG. 2 is a schematic cross-sectional view showing another example of a plasma processing apparatus 100 according to one embodiment. The plasma processing apparatus 100 shown in FIG. 2 is different from the plasma processing apparatus 100 shown in FIG. 1 in the shapes and positions of the electromagnetic wave emission part 7 and the multipactor discharge part 15. Since the other device configurations are the same, the shapes and positions of the electromagnetic wave emission part 7 and the multipactor discharge part 15 will be described.

The electromagnetic wave emission part 7 is disposed at the end point of the waveguide 9. The lower part of the electromagnetic wave emission part 7 protrudes toward the inner circumference, and surrounds the notch of the upper electrode 5 that disposed at the outer circumference of the upper electrode 5 from the outer circumference thereof. The multipactor discharge part 15 is disposed at a position in contact with the plasma generation space U, the upper electrode 5, and the electromagnetic wave emission part 7, and has an L-shaped gap (space) in radial cross-sectional view. In other words, the multipactor discharge part 15 extends horizontally from the outer circumference of the multipactor discharge part 15 along the lower protrusion of the electromagnetic wave emission part 7, and is bent vertically at an angle of 90° along the upper corner of the protrusion to constitute a gap facing the plasma generation space U.

When the electromagnetic waves that travel radially in a horizontal direction through the waveguide 9 are brought into contact with the inner surface of the processing chamber 1, they travels downward, pass through the electromagnetic wave emission part 7. Then, they are emitted from the inner tip surface of the lower protrusion and the multipactor discharge part 15 into the plasma generation space U, and travel horizontally toward the central axis of the processing chamber 1.

### Multipactor Discharge Part

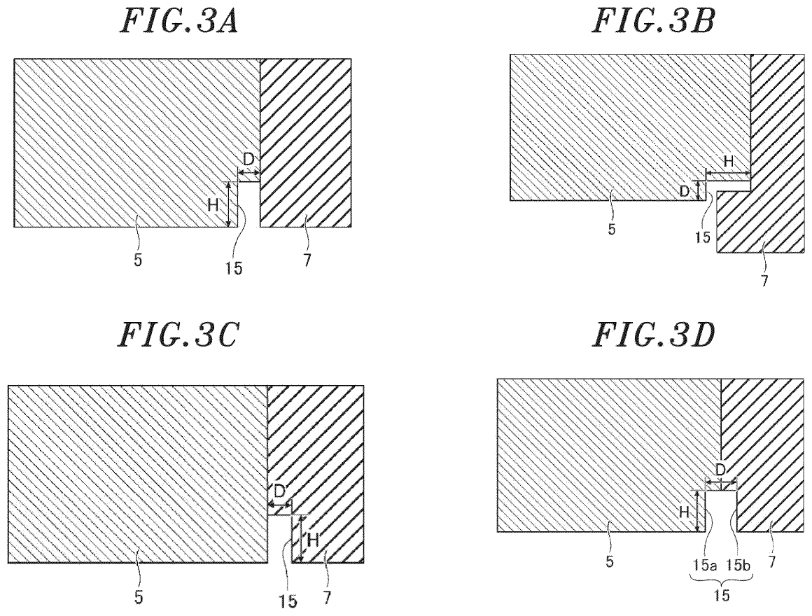

Modifications of the multipactor discharge part 15 will be described with reference to FIGS. 3A to 3D. FIG. 3A is an enlarged view of the multipactor discharge part 15 shown in FIG. 1. FIG. 3B is an enlarged view of the multipactor discharge part 15 shown in FIG. 2. The multipactor discharge part 15 of FIGS. 3C and 3D is an example of another modification of the multipactor discharge part 15 that may be included in the plasma processing apparatus 100.

The multipactor discharge part 15 shown in FIG. 3A is formed at the lower outer circumferential corner of the upper electrode 5, whereas the multipactor discharge part 15 shown in FIG. 3C is formed at the lower inner circumferential corner of the electromagnetic wave emission part 7. The multipactor discharge part 15 shown in FIG. 3C is formed as a notch formed on the electromagnetic wave emission part 7 side, and is formed as a gap having a rectangular cross section in a radial direction formed around the entire circumference and facing the plasma generation space U. The multipactor discharge part 15 shown in FIG. 3D is formed as notches 15a and 15b formed at the lower outer circumferential corner of the upper electrode 5 and the lower inner circumferential corner of the electromagnetic wave emission part 7 opposing thereto, and is formed as a gap having a rectangular cross section in a radial direction formed around the entire circumference and facing the plasma generation space U.

It is preferable that the gaps of the multipactor discharge parts 15 shown in FIGS. 3A to 3D is formed around the entire circumference. This is because the margin for plasma ignition increases, and plasma can be formed uniformly in the circumferential direction. However, it is unnecessary that the gap of the multipactor discharge part 15 is formed around the entire circumference.

If the notch (irregularity) for forming the multipactor discharge part 15 where the electric field is concentrated is formed on the electromagnetic wave emission part 7 side, the corners and edges of the dielectric are easily damaged. Therefore, among the multipactor discharge parts 15 shown in FIGS. 3A to 3D, the configurations of FIGS. 3A and 3B in which the notch is formed at the metallic upper electrode 5 are more preferable. However, it is also possible to adopt the configurations of the multipactor discharge parts 15 in FIGS. 3C and 3D.

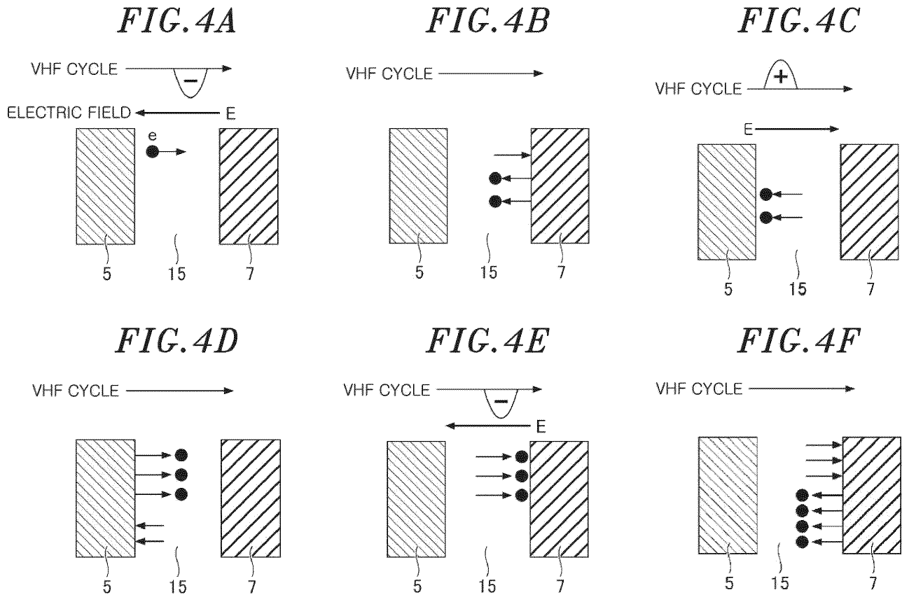

FIG. 4 is a diagram for explaining multipactor discharge. When electromagnetic waves having a high frequency such as a VHF band or a microwave band are supplied from the power supply 11, it is possible to provide the multipactor discharge part 15 in the processing chamber 1. In the case of a high frequency lower than 30 MHz, the wavelength becomes longer, and the gap of the multipactor discharge part 15 needs to be increased to cause multipactor discharge. Hence, it is difficult to provide such a structure at the portion of the upper electrode 5 that is brought into contact with the plasma. In the present embodiment, electromagnetic waves in a VHF band or a microwave band are supplied from the power supply 11, and plasma ignition can be promoted by the following structure of the multipactor discharge part 15.

In the plasma processing apparatus 100 of the present disclosure, the notch (groove) is formed at the lower outer corner of the upper electrode 5. Further, the distance between the facing surfaces of the upper electrode 5 and the electromagnetic wave emission part 7 (the distance of the gap of the multipactor discharge part 15) is set to 1 mm to 10 mm (about 1/300 of the wavelength of the electromagnetic wave in vacuum) to create a multipactor generation resonance space, thereby promoting plasma ignition.

When electromagnetic waves in a VHF band (hereinafter, also referred to as “VHF waves”) are supplied from the power supply 11 to the upper electrode 5, for example, electrons are accelerated by electric field E generated at the multipactor discharge part 15. As shown in FIG. 4A, in a negative cycle of the VHF waves, the direction of the electric field E is directed from the electromagnetic wave emission part 7 to the upper electrode 5. Accordingly, the electrons e are accelerated from the upper electrode 5 toward the electromagnetic wave emission part 7. When the accelerated electrons collide with the sidewall of the electromagnetic wave emission part 7, as shown in FIG. 4B, the electrons are emitted from the sidewall of the electromagnetic wave emission part 7 that is made of a dielectric material such as alumina or the like.

When the timing at which the direction of the electric field E is switched and the timing at which the electrons collide with the wall are substantially the same, the emitted electrons can be accelerated. In other words, when the cycle of the VHF waves is set as T and the average time required for electrons to reach the electromagnetic wave emission part 7 from the upper electrode 5 or the average time required for electrons to reach the upper electrode 5 from the electromagnetic wave emission part 7 is set as t₀, the multipactor discharge is promoted when T/2≈t₀ is satisfied.

When the timing at which the electrons shown in FIG. 4B collide with the wall of the electromagnetic wave emission part 7 is substantially the same as the timing at which the VHF waves are switched from a negative cycle to a positive cycle, the direction of the electric field E is switched to a direction from the upper electrode 5 toward the electromagnetic wave emission part 7 as shown in FIG. 4C. Accordingly, the electrons emitted from the electromagnetic wave emission part 7 can be accelerated toward the upper electrode 5 as shown in FIG. 4C.

In the same manner, when the timing at which the electrons collide with the wall of the upper electrode 5 and the timing at which the VHF waves are switched from a positive cycle to a negative cycle are substantially the same, the electrons emitted from the upper electrode 5 can be accelerated toward the electromagnetic wave emission part 7 (see FIGS. 4D and 4E). If the collision and acceleration of the electrons occurs repeatedly, the number of electrons increases to a predetermined number or more, as shown in FIG. 4F, and plasma ignition occurs.

Compared to the discharge according to Paschen's law, the multipactor discharge is characterized in that the acceleration of electrons emitted from the wall due to the collision by applying more energy to the electrons and the emission of a larger number of electrons by collision with the facing wall are repeated. By using the VHF waves (30 MHz to 300 MHZ) or the microwaves (300 MHz to 3 THz) of which wavelength is shorter than that of high frequency waves of less than 30 MHz, the timing at which the electric field is switched and the timing at which the electrons collide with the wall can become substantially the same. Accordingly, more energy can be applied to the emitted electrons, and the electrons can be accelerated.

From the above, it is clear that multipactor discharge is likely to occur by designing the distance D of the gap shown in FIG. 3 such that the timing at which the VHF waves are switched from a positive cycle to a negative cycle or from a negative cycle to a positive cycle at 1/2 cycle becomes the same as the timing at which the electrons collide with the wall of the upper electrode 5 or the electromagnetic wave emission part 7.

When the VHF waves are supplied to the upper electrode 5, the average speed of electrons in the electric field of the multipactor discharge part 15 at time t is expressed by Eq. (1).

$${v}_{e} [ m / s ] = {\int }_{0}^{t} \frac{e}{{m}_{e}} {E}_{0} cos ( ω t ) dt = \frac{e}{{m}_{e} ω} {E}_{0} sin ( ω t ) \qquad Eq . ( 1 )$$

In Eq. (1), e indicates an elementary charge, E₀ indicates an amplitude of the electric field, mₑ indicates a mass of an electron, and ω indicates an angular frequency. For example, when the VHF waves of 220 MHz are supplied, the angular frequency ω is calculated from ω=2πF.

Time T/2 can be calculated from 2.2×10⁻⁹s that is 1/2 the cycle at the frequency F of 220 MHz. The maximum movement distance of the electrons at 1/2 cycle is calculated using Eq. (2) to be 3.8 mm by substituting, e.g., 2×10⁴ V/m, for the standard electric field E₀ (the amplitude of the electric field) applied to the upper electrode 5, wherein e is 1.60×10⁻¹⁹ (C), mₑ is 9.1×10⁻³¹ (kg), and ω=2πF.

$$D [ mm ] = {\int }_{0}^{T / 2} {v}_{e} dt = \frac{{2}_{e} {E}_{0}}{{m}_{e} {ω}^{2}} = 3.8 \qquad Eq . ( 2 )$$

Accordingly, if the distance D of the gap between the facing surfaces of the upper electrode 5 and the electromagnetic wave emission part 7 is 3.8 mm, the possibility of multipactor discharge increases.

### (Aspect Ratio)

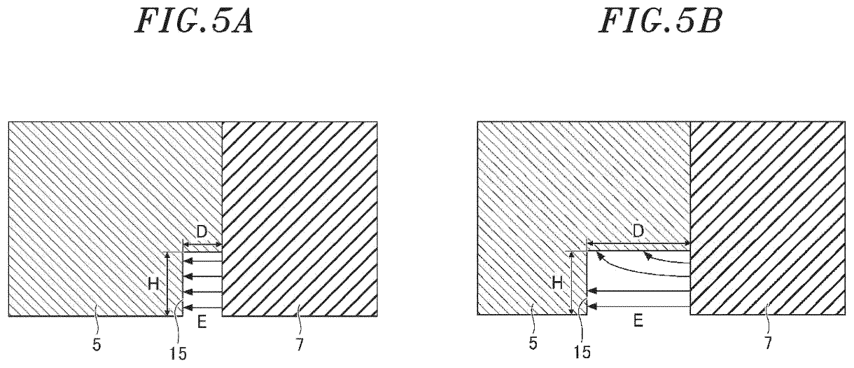

Further, the aspect ratio indicating a depth H with respect to the distance D (the distance of the gap of the multipactor discharge part 15) shown in FIG. 3 is preferably 1 or more. FIGS. 5A and 5B are diagrams for explaining the aspect ratio of the multipactor discharge part 15 according to one embodiment. FIG. 5A shows a case where the gap of the multipactor discharge part 15 is designed such that the aspect ratio (H/D) becomes 1 or more, and FIG. 5B shows a case where the gap of the multipactor discharge part 15 is designed such that the aspect ratio (H/D) becomes less than 1.

In view of the collision of the electrons and the emission of the electrons shown in FIG. 4, it is preferable that the electric field E generated in the gap of the multipactor discharge part 15 is directed in the horizontal direction. When the aspect ratio shown in FIG. 5A is 1 or more, the electric field E is directed in the horizontal direction. By uniformly directing the electric field E in one direction toward the facing surfaces of the upper electrode 5 and the electromagnetic wave emission part 7, the distance D of the gap corresponding to the optimal multipactor discharge can be defined, which makes it possible to increase the probability of collision of electrons. On the other hand, when the aspect ratio shown in FIG. 5B is less than 1, a part of the electric field E is bent toward the sidewall near the wall from which the electrons are emitted, and the electrons are also bent in the direction of the electric field E. Accordingly, the collision of the electrons is reduced and the multipactor discharge is less likely to occur. From the above, it is preferable that the aspect ratio (H/D) is 1 or more. Hence, the collision of electrons increases, so that the plasma can be ignited stably and the ignition timing can be advanced.

Further, the gap of the multipactor discharge part 15 may be designed such that the aspect ratio (H/D) becomes 5 or less. If the aspect ratio is excessively large, the rear side (the side opposite to the side opened toward the plasma generation space) of the gap of the multipactor discharge part 15 becomes far from the plasma generation space U, and the electric field E at the rear side of the gap does not contribute to the generation of plasma. From the above, it is preferable that the aspect ratio (H/D) is 1 or more and 5 or less. Accordingly, the plasma ignition can become stable, and the electrons generated by the multipactor discharge can be efficiently diffused into the plasma generation space U, thereby increasing the plasma generation efficiency.

### Relationship Between Distance of Multipactor Discharge Part and Frequency of High Frequency Waves

The relationship between the distance D of the multipactor discharge part 15 and the frequency F of the VHF waves will be explained. The structure of the upper electrode 5 having a metallic shower structure and the electromagnetic wave emission part 7 made of a dielectric material (alumina) shown in FIG. 1 is regarded as a concentric capacitor. When the VHF waves are supplied from the power supply 11 to the upper electrode 5, the magnitude of the characteristic impedance of the electromagnetic wave emission part 7 at a frequency of 220 MHz is calculated using Eq. (3).

$$\vert {Z}_{c} \vert = \frac{ln ( b / a )}{ω \cdot 2 πε l} = \frac{ln ( 215 / 175 )}{2 π \cdot 220 \cdot {10}^{6} \cdot 2 π \cdot 8.8 \cdot {10}^{- 12} \cdot 10 \cdot 5 \cdot {10}^{- 2}} = 5.3 [ Ω ] \qquad Eq . ( 3 )$$

As shown in FIG. 1, b indicates the radial distance from the central axis of the plasma processing apparatus 100 to the inner surface of the sidewall of the processing chamber 1, which is 215 mm. a indicates the radial distance from the central axis of the plasma processing apparatus 100 to the outer circumferential surface of the upper electrode 5, which is 175 mm.

When the frequency F is 220×10⁶ Hz, ω is 2π×220×10⁶. When the dielectric constant of vacuum is set as ε₀, and the relative dielectric constant of alumina is set as εᵣ, the dielectric constant ε of a part of the electromagnetic wave emission part 7 is calculated as ε₀×εᵣ=8.8×10⁻¹²×10. 1 indicates the height of the electromagnetic wave emission part 7 shown in FIG. 1, which is 5x10⁻² mm.

By substituting the above into Eq. (3), the characteristic impedance |Z_{c}| is calculated to be 5.3 Ω. Accordingly, the voltage applied to the alumina electromagnetic wave emission part 7 is calculated to be 73 V using Eq. (4).

$$V = \sqrt{P \vert {Z}_{C} \vert} = \sqrt{1000 \cdot 5.3} = 73 [ V ] \qquad Eq . ( 4 )$$

P is the power of the VHF waves, which is set to 1000 W. The electric field E applied to the electromagnetic wave emission part 7 made of alumina is the electric field E_{Al2O3⊥} in the direction indicated by D of the gap of the multipactor discharge part 15, and is expressed as E=E_{Al2O3⊥}=V/W. The voltage V applied to the electromagnetic wave emission part 7 made of alumina is calculated to be 73 V using Eq. (4), and W is 40 mm as shown in FIG. 1. Therefore, it is calculated to be 1830 V/m using Eq. (5).

$$E = {E}_{Al 2 O 3 ⊥} = \frac{73}{0.04} = 1830 [ V / m ] \qquad Eq . ( 5 )$$

The vertical component D_{vacuum⊥} of the electric flux density at the boundary surface between the vacuum gap of the multipactor discharge part 15 and the wall of the electromagnetic wave emission part 7 is equal to the electric flux density D_{Al2O3⊥} of alumina (the electromagnetic wave emission part 7). In other words, according to Maxwell's law, the electric flux density can be expressed by an equation due to the vertical continuity at the boundary surface between the gap of the multipactor discharge part 15 and the alumina of the electromagnetic wave emission part 7. Therefore, the following equation is satisfied.

$${ε}_{vacuum} {E}_{vacuum ⊥} = {ε}_{Al 2 O 3} {E}_{Al 2 O 3 ⊥}$$

The dielectric constant ε of the vacuum gap is equal to the dielectric constant ε₀ of the vacuum, and E_{Al2O3⊥}is calculated to be 1830 V/m using Eq. (5). Further, ε_{Al2O3⊥}/ε_{vacuum} is 10. From the above, the electric field Evacuum in the direction indicated by D of the gap of the multipactor discharge part 15 is calculated to be about 18300 V/m.

P indicating the power of the VHF waves was calculated to be 1000 W. When P is set to 500 W, the electric field Eₚ applied to the alumina of the electromagnetic wave emission part 7 is calculated to be about 1300 V/m from Eq. (6), and the electric field E_{vacuum⊥} in the direction indicated by D of the gap of the multipactor discharge part 15 is calculated to be about 13000 V/m. Further, when P is set to 2000 W, the electric field Eₚ applied to the alumina of the electromagnetic wave emission part 7 is calculated to be about 2600 V/m from Eq. (6), and the electric field E_{vacuum⊥} in the direction indicated by D of the gap of the multipactor discharge part 15 is calculated to be about 26000 V/m.

$${E}_{p} = 1830 \times \sqrt{\frac{P}{1000}} \qquad Eq . ( 6 )$$

The following Eq. (7) is a generalized version of Eq. (2).

$$D [ m ] = \frac{2 {eE}_{vacuum ⊥}}{{m}_{e} {ω}^{2}} = \frac{2 e}{{m}_{e} {ω}^{2}} \frac{{ε}_{Al 2 O 3}}{W} \sqrt{\frac{P \cdot ln ( b / a )}{ω \cdot 2 πε l}} \qquad Eq . ( 7 )$$

Eq. (7) can be expanded as follows by taking logarithms on both sides, thereby obtaining Eq. (8).

$$ln ( D ) = ln ( \frac{2 e}{{m}_{e} {ω}^{2}} \frac{{ε}_{Al 2 O 3}}{W} ) + \frac{1}{2} ln ( \frac{P \cdot ln ( b / a )}{ω \cdot 2 πε l} ) = - 2 ln ( ω ) + ln ( \frac{2 e}{{m}_{e}} \frac{{ε}_{Al 2 O 3}}{W} ) - \frac{1}{2} ln ( ω ) + \frac{1}{2} ln ( \frac{P \cdot ln ( b / a )}{ω \cdot 2 πε l} ) = - \frac{5}{2} ln ( ω ) + ln ( \frac{2 e}{{m}_{e}} \frac{{ε}_{Al 2 O 3}}{W} ) + \frac{1}{2} ln ( \frac{P \cdot ln ( b / a )}{2 πε l} ) \qquad Eq . 8$$

The following Eq. (9) is obtained from Eq. (8) by setting y=In (D) and x=In (w).

$$y = - \frac{5}{2} + ln ( \frac{2 e}{{m}_{e}} \frac{{ε}_{Al 2 O 3}}{W} ) + \frac{1}{2} ln ( \frac{P \cdot ln ( b / a )}{2 πε l} ) \qquad Eq . ( 9 )$$

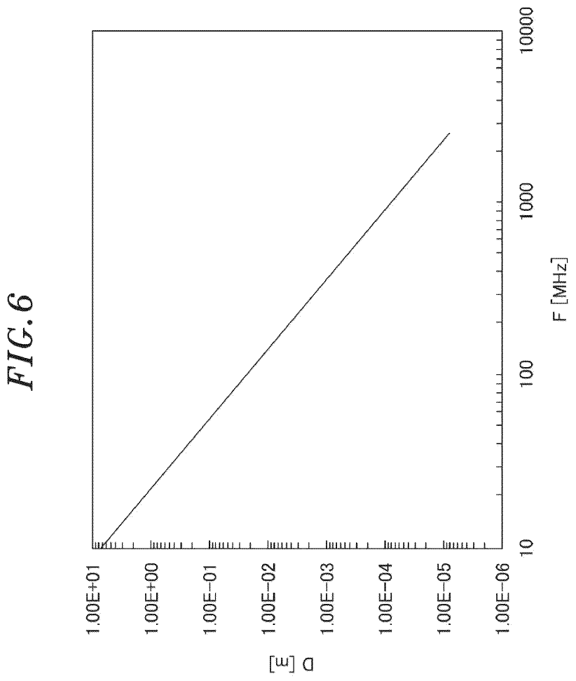

Accordingly, as shown in FIG. 6, it is clear that the logarithm (vertical axis) of the distance D of the optimal gap of the multipactor discharge part 15 and the logarithm (horizontal axis) of the frequency F that is the frequency of the electromagnetic waves supplied from the power supply 11 are in a linear function relationship.

According to Eq. (9), when the power P of the VHF waves is changed from 500 W to 2000 W, if the frequency F of the VHF waves is set to 200 MHz, the distance D of the gap becomes 2.6 mm for 3/8 cycle (=1/2 cycle−1/8 cycle) of the VHF waves. Further, the distance D of the gap is 4.3 mm for 1/2 cycle of the VHF waves. Further, the distance D of the gap is 7.0 mm for 5/8 cycle (=1/2 cycle+1/8 cycle) of the VHF waves.

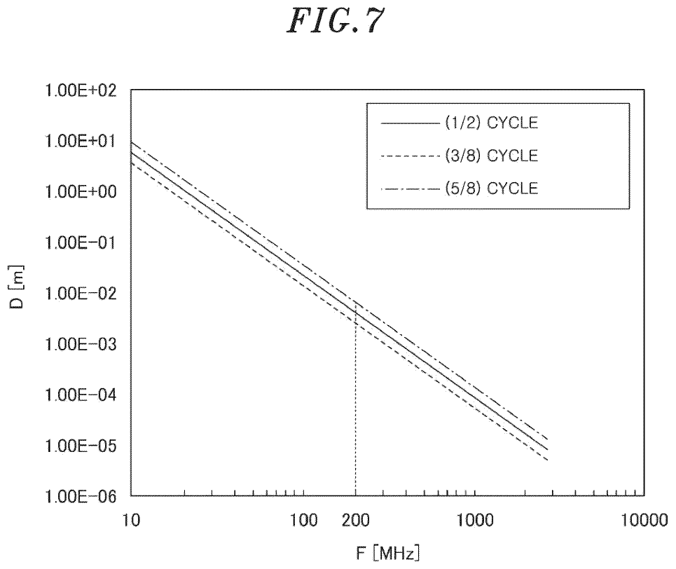

FIG. 7 shows the relationship between the frequency F of the VHF waves and the distance D of the gap for 3/8 cycle, 1/2 cycle, and 5/8 cycle of the VHF waves. When the frequency F of the VHF waves is set to 200 MHZ, if the distance D of the gap of the multipactor discharge part 15 exceeds the range of 2.6 mm to 7.0 mm, the deceleration of electrons per half cycle shown in FIG. 4 increases. Accordingly, the resonance phenomenon is unlikely to occur and, thus, the multipactor discharge is unlikely to occur.

Therefore, the distance D of the gap is set to be the movement distance of the electrons moving for a time period of 1/2 cycle±1/8 cycle of the electromagnetic waves and cause multipactor discharge in the gap. Further, the time period of 1/8 cycle used here is a time period set from experience as an allowable time for causing multipactor discharge.

As described above, in accordance with the present embodiment, it is possible to provide the plasma processing apparatus 100 capable of stably igniting plasma.

The plasma processing apparatus is preferably applied to an ALD apparatus. In an ALD apparatus, ON and OFF of plasma is repeatedly controlled in a short period of time. Therefore, it is important to perform impedance matching at a high speed and ignite plasma at a high speed. In this respect, the plasma processing apparatus 100 of the present disclosure can stably ignite plasma in a short period of time, and thus is suitable for an ALD apparatus.

The plasma processing apparatus according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

This application claims priority to Japanese Patent Application No. 2022-098827 filed on Jun. 20, 2022, the entire contents of which are incorporated herein by reference.

1. A plasma processing apparatus comprising:
a processing chamber where a plasma generation space is formed;
an electrode to which electromagnetic waves for generating plasma are applied;
a waveguide disposed along an outer circumference of the electrode;
an electromagnetic wave emission part made of a dielectric material and configured to emit the electromagnetic waves into the plasma generation space; and
a multipactor discharge part that is a gap formed between the electrode and the electromagnetic wave emission part and faces the plasma generation space.

2. The plasma processing apparatus of claim 1, wherein the multipactor discharge part is formed, as a notch of at least one of the electrode or the electromagnetic wave emission part, between the electrode and the electromagnetic wave emission part.

3. The plasma processing apparatus of claim 1, further comprising:
a power supply configured to supply electromagnetic wave power to the electrode,
wherein, when a distance of the gap between facing surfaces of the electrode and the electromagnetic wave emission part is set as D and a frequency of the electromagnetic waves supplied from the power supply is set as F, a logarithm of the distance D of the gap and a logarithm of the frequency F of the electromagnetic waves are in a linear function relationship.

4. The plasma processing apparatus of claim 3, wherein the distance D of the gap is a movement distance of electrons moving for a time period of 1/2 cycle±1/8 cycle of the electromagnetic waves and cause multipactor discharge in the gap.

5. The plasma processing apparatus of claim 1, wherein an aspect ratio of the gap of the multipactor discharge part is 1 or more.

6. The plasma processing apparatus of claim 5, wherein the aspect ratio of the gap of the multipactor discharge part is 5 or less.

7. The plasma processing apparatus of claim 2, wherein the multipactor discharge part is formed, as a notch of the electrode, around the entire circumference of the electrode.

8. The plasma processing apparatus of claim 7, wherein the electromagnetic wave emission part is disposed at an end point of the waveguide, and surrounds the notch of the electrode disposed at the outer circumference of the electrode from the outer circumference thereof.

9. The plasma processing apparatus of claim 1, wherein the electromagnetic waves are in a VHF band or a microwave band.

10. The plasma processing apparatus of claim 1, wherein the plasma processing apparatus is an atomic layer deposition (ALD) apparatus.
